(19) United States
(12) Patent Application Publication
(10) Pub. No.: US 2014/0034359 A1
(43) Pub. Date: Feb. 6, 2014

(54) PRINTED CIRCUIT BOARD AND METHOD OF MANUFACTURING PRINTED CIRCUIT BOARD

(71) Applicant: SAMSUNG ELECTRO-MECHANICS CO., LTD., Suwon (KR)

(72) Inventors: Jeong Woo Lee, Suwon (KR); Going Sik Kim, Suwon (KR)

(73) Assignee: SAMSUNG ELECTRO-MECHANICS CO., LTD., Suwon (KR)

(21) Appl. No.: 13/958,196

(22) Filed: Aug. 2, 2013

(30) Foreign Application Priority Data
Aug. 3, 2012 (KR) 10-2012-0085307

(51) Int. Cl. H05K 3/02; H05K 3/06; H05K 1/11

(52) U.S. Cl. CPC H05K 3/027; H05K 1/115; H05K 3/06
USPC 174/251; 216/13; 430/319; 430/312

(57) ABSTRACT

Disclosed herein is a printed circuit board including a base substrate, a photosensitive insulating layer formed on an upper portion of the base substrate, and a circuit pattern formed to be buried within the photosensitive insulating film.

### CROSS REFERENCE TO RELATED APPLICATION

This application claims the benefit of Korean Patent Application No. 10-2012-0085307, filed on Aug. 3, 2012, entitled “Printed Circuit Board and Method of Manufacturing a Printed Circuit Board”, which is hereby incorporated by reference in its entirety into this application.

### BACKGROUND OF THE INVENTION

1. Technical Field

The present invention relates to a printed circuit board and a method of manufacturing a printed circuit board.

2. Description of the Related Art

Recently, a demand for a technique of directly mounting semiconductor chips on a printed circuit board (PCB) to cope with high density of semiconductor chips and a high speed of signal transmission is increasing, and in line with this, the development of a PCB having high density and high reliability to cope with the high density of semiconductor chips is required.

Requirements for a PCB having high density and high reliability are closely related to specifications of a semiconductor chip, and obtaining finer circuits, a high level of electrical characteristics, a high speed signal transmission structure, high reliability, high functionality, and the like, are on the issue to be tackled. In order to address these problems, a PCB technique allowing for a formation of micro-via holes is required (U.S. Pat. No. 6,240,636).

### SUMMARY OF THE INVENTION

The present invention has been made in an effort to provide a printed circuit board and a method of manufacturing a printed circuit board capable of forming a plurality of via holes by using exposure and development without increasing a process time and cost.

The present invention has also been made in an effort to provide a printed circuit board and a method of manufacturing a printed circuit board capable of simultaneously forming a via and a circuit pattern to thus reduce a process time.

The present invention has also been made in an effort to provide a printed circuit board and a method of manufacturing a printed circuit board capable of increasing a degree of freedom in designing a circuit pattern.

The present invention has also been made in an effort to provide a printed circuit board and a method of manufacturing a printed circuit board capable of reducing noise of an electrical signal in electrically connecting layers by a circuit pattern and a via formed within a photosensitive insulating layer.

According to an embodiment of the present invention, there is provided a printed circuit board including: a base substrate; a photosensitive insulating layer formed on an upper portion of the base substrate; and a circuit pattern formed to be buried within the photosensitive insulating film.

The photosensitive insulating layer may include a first photosensitive insulating film formed on an upper portion of the base substrate and a second photosensitive insulating film formed on an upper portion of the first photosensitive insulating film.

The first photosensitive insulating film and the second photosensitive insulating may have different levels of sensitivity.

The first photosensitive insulating film may have a lower level of sensitivity than that of the second photosensitive insulating film.

The circuit pattern may include: a first circuit pattern formed on an upper portion of the base substrate and formed to be buried within the first photosensitive insulating film; a via lower portion formed on an upper portion of the first circuit pattern; and a second circuit pattern formed to be buried within the second photosensitive insulating film and formed on an upper portion of the via lower portion.

The printed circuit pattern may further include a third circuit pattern formed on at least one of an upper portion of the second photosensitive insulating film, the via upper portion, and an upper portion of the second circuit pattern.

The photosensitive insulating layer may further include: a third photosensitive insulating film formed on an upper portion of the second photosensitive insulating film and formed to be buried within the third circuit pattern formed on the upper portion of the second photosensitive insulating film.

According to another embodiment of the present invention, there is provided a method of manufacturing a printed circuit board, including: preparing a base substrate having a first circuit pattern formed thereon; forming a photosensitive insulating layer on an upper portion of the base substrate; exposing and developing the photosensitive insulating layer to form a first via hole and a second circuit pattern hole; and forming a first via and a second circuit pattern in the first via hole and the second circuit pattern hole.

In the forming of the photosensitive insulating layer, the photosensitive insulating layer may include a first photosensitive insulating film and a second photosensitive insulating film.

The first photosensitive insulating film and the second photosensitive insulating film may have different levels of sensitivity.

The first photosensitive insulating film may have a lower level of sensitivity than that of the second photosensitive insulating film.

The first photosensitive insulating film and the second photosensitive insulating film may be formed as negative photosensitive insulating films.

The forming of the first via hole and the second circuit pattern hole may include: performing an exposing operation on a region other than regions in which the first via and the second circuit pattern are to be formed on the photosensitive insulating layer; developing the second photosensitive insulating film to form the first via hole upper portion and the second circuit pattern hole; performing an exposing operation on the first photosensitive insulating film exposed through the second circuit pattern hole; and developing the first photosensitive insulating film to form a first via hole lower portion.

The first photosensitive insulating film and the second photosensitive insulating film may be formed as positive photosensitive insulating films.

The forming of the first via hole and the second circuit pattern hole may include: exposing regions of the second photosensitive insulating film in which the first via and the second circuit pattern are to be formed; developing the exposed second photosensitive insulating film to form the first via hole upper portion and the second circuit pattern hole; exposing the first photosensitive insulating film exposed through the first via hole upper portion; and developing the exposed first photosensitive insulating film to form the first via hole lower portion.

The method may further include: after the forming of the first via and the second circuit pattern, forming a third circuit pattern on at least one of an upper portion of the second photosensitive insulating film, the via upper portion, and an upper portion of the second circuit pattern.

The forming of the third circuit pattern may include: forming a plated layer on an upper portion of the second photosensitive insulating film, the first via upper portion, and an upper portion of the second circuit pattern; forming an etching resist in a region in which the third circuit pattern is to be formed; etching the plated layer exposed by the etching resist; and removing the etching resist.

The plated layer may be formed simultaneously when the first via and the second circuit pattern are formed.

The forming of the third circuit pattern may include: forming a plated resist on an upper portion of the second photosensitive insulating film and having an opening exposing the region in which the third circuit pattern is to be formed; forming the third circuit pattern in the opening of the plated resist; and removing the plated resist.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplary view illustrating a printed circuit board according to an embodiment of the present invention.

FIGS. 2 through 10 are exemplary views illustrating a method of manufacturing a printed circuit board according to an embodiment of the present invention.

FIGS. 11 through 19 are exemplary views illustrating a method of manufacturing a printed circuit board according to an embodiment of the present invention.

FIGS. 20 and 21 are exemplary views illustrating a method of manufacturing a printed circuit board according to another embodiment of the present invention.

FIGS. 22 and 23 are exemplary views illustrating a method of manufacturing a printed circuit board according to another embodiment of the present invention.

FIG. 24 is an exemplary view illustrating a printed circuit board having a multilayer structure according to an embodiment of the present invention.

FIG. 25 is an exemplary view illustrating a printed circuit board having a multilayer structure according to another embodiment of the present invention.

FIG. 26 is an exemplary view illustrating a printed circuit board having a multilayer structure according to another embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 1 is an exemplary view illustrating a printed circuit board according to an embodiment of the present invention.

Referring to FIG. 1, a printed circuit board (PCB) 100 may include a base substrate 110, a first circuit pattern 120, a photosensitive insulating layer 130, a first via 170, and a second circuit pattern 160.

The base substrate 110 may be made of a composite polymer resin generally used as an interlayer insulating material. For example, the PCB may be fabricated to be thinner by employing a pre-preg as the base substrate 110. Or, a fine circuit may be easily implemented by employing the Ajinomoto build up film (ABF) as the base substrate 110. Besides, the base substrate 110 may be made of an epoxy-based resin such as FR-4, BT (Bismaleimide Triazine), or the like, but the present invention is not particularly limited thereto. Also, a copper clad laminate (CCL) may be used as the base substrate 110. In an embodiment of the present invention, a CCL may be used as the base substrate 110.

The first circuit pattern 120 may be formed on an upper portion of the base substrate 110. The first circuit pattern 120 may be formed by using a general circuit pattern forming method. The first circuit pattern 120 according to an embodiment of the present invention may be formed by patterning a copper foil of the CCL as the base substrate 110.

The photosensitive insulating layer 130 may be formed above the substrate 110 and the first circuit pattern 120. The photosensitive insulating layer 130 may include a first photosensitive insulating film 131 and a second photosensitive insulating film 132. The first photosensitive insulating film 131 may be formed at an upper portion of the base substrate 110 and the first circuit pattern 120. The second photosensitive insulating film 132 may be formed on an upper portion of the first photosensitive insulating film 131. According to an embodiment of the present invention, the first photosensitive insulating film 131 and the second photosensitive insulating film 132 may have different levels of sensitivity. For example, the first photosensitive insulating film 131 may be formed to have a lower level of sensitivity than that of the second photosensitive insulating film 132.

The first via 170 may be formed on an upper portion of the first circuit pattern 120. The first via 170 may be formed to penetrate the photosensitive insulating layer 130. Namely, a lower portion of the first via 170 may be formed on the first photosensitive insulating film 131. Also, an upper portion of the first via 170 may be formed on the second photosensitive insulating film 132.

The first via 170 may be made of a conductive material. Namely, the first via 170 may be electrically connected to the first circuit pattern 120. The first via 170 may be made of the same material as that of the first circuit pattern 120.

The second circuit pattern 160 may be formed within the photosensitive insulating layer 130. For example, the second circuit pattern 160 may be formed to be buried within the second photosensitive insulating film 132. The second circuit pattern 160 may be made of a conductive material. Also, the second circuit pattern 160 may be made of the same material as that of the first circuit pattern 120 or the first via 170.

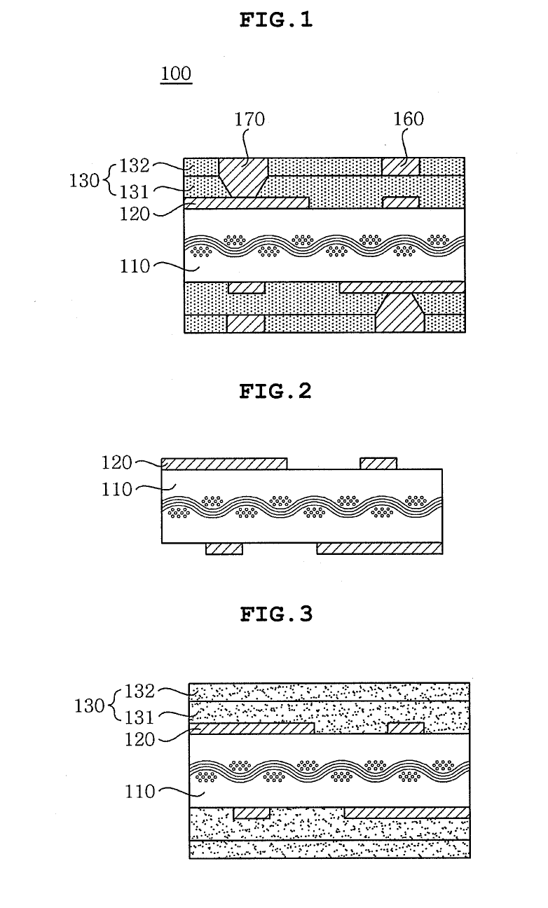

FIGS. 2 through 10 are exemplary views illustrating a method of manufacturing a printed circuit board according to an embodiment of the present invention.

Referring to FIG. 2, the base substrate 110 with the first circuit pattern 120 formed thereon is prepared. The base substrate 110 may be made of a composite polymer resin generally used as an interlayer insulating material. For example, the PCB may be fabricated to be thinner by employing a pre-preg as the base substrate 110. Or, a fine circuit may be easily implemented by employing an Ajinomoto build up film (ABF) as the base substrate 110. Besides, the base substrate 110 may be made of an epoxy-based resin such as FR-4, BT (Bismaleimide Triazine), or the like, but the present invention is not particularly limited thereto. Also, a copper clad laminate (CCL) may be used as the base substrate 110. In an embodiment of the present invention, a CCL may be used as the base substrate 110.

The first circuit pattern 120 may be formed on an upper portion of the base substrate 110. The first circuit pattern 120 may be made of a conductive metal such as copper (Cu), gold (Au), nickel (Ni), or the like. In an embodiment of the present invention, the first circuit pattern 120 may be formed by patterning a copper foil of a copper clad laminate (CCL). Although not shown in FIG. 2, a through via may be formed to penetrate the base substrate 110.

Referring to FIG. 3, the photosensitive insulating layer 130 may be formed on an upper portion of the base substrate 110 and the first circuit pattern 120. The photosensitive insulating layer 130 may include the first photosensitive insulating film 131 and the second photosensitive insulating film 132.

The first photosensitive insulating film 131 may be attached to the first circuit pattern 120 and the base substrate 110. The second photosensitive insulating film 132 may be attached to an upper portion of the first photosensitive insulating film 131. Although not shown in FIG. 3, a metal layer (not shown) may be formed on an upper portion of the second photosensitive insulating film 132. In this case, after the second photosensitive insulating film 132 is formed on an upper portion of the first photosensitive insulating film 131, the metal layer (not shown) may be etched.

The first photosensitive insulating film 131 and the second photosensitive insulating film 132 may have different levels of sensitivity. For example, the first photosensitive insulating film 131 may have a lower level of sensitivity than that of the second photosensitive insulating film 132. Or, the first photosensitive insulating film 131 may have a higher level of sensitivity than that of the second photosensitive insulating film 132. The levels of sensitivity of the first photosensitive insulating film 131 and the second photosensitive insulating film 132 may be different according to a change in a photo initiator, a filler, and the like. In an embodiment of the present invention, the first photosensitive insulating film 131 having a lower level of sensitivity than that of the second photosensitive insulating film 132 may be used. Also, the first photosensitive insulating film 131 and the second photosensitive insulating film 132 may be negative photosensitive insulating films.

Since the first photosensitive insulating film 131 and the second photosensitive insulating film 132 having different levels of sensitivity are used, when partial exposure is performed in a follow-up stage, an exposure region may be effectively controlled. For example, when an exposing operation is performed only on the second photosensitive insulating film 132, only the second photosensitive insulating film 132 may be exposed due to a difference between the levels of sensitivity of the first photosensitive insulating film 131 and the second photosensitive insulating film 132. In this manner, fine patterning may be performed by using the difference between the levels of sensitivity of the first photosensitive insulating film 131 and the second photosensitive insulating film 132 and a quantity of light.

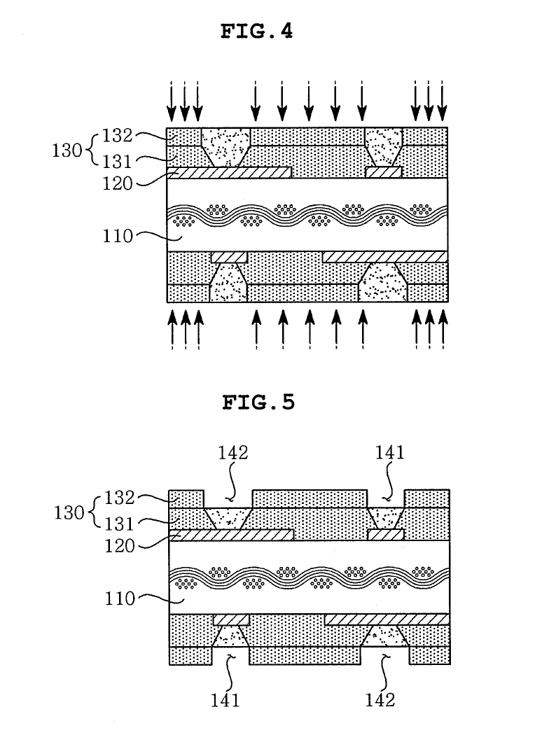

Referring to FIG. 4, a first exposing operation may be performed on the photosensitive insulating layer 130. During the first exposing operation, both the first photosensitive insulating film 131 and the second photosensitive insulating film 132 may be exposed by adjusting the amount of exposure. Here, the exposing operation may be performed on the photosensitive insulating layer 130 excluding portions in which the second circuit pattern 160 and the first via 170 are to be formed.

Referring to FIG. 5, a primary developing operation may be performed on the photosensitive insulating layer 130. By performing the primary developing operation, the second photosensitive insulating film 132 at an upper portion of the first via 170 and a portion in which the second circuit pattern 160 is to be formed may be removed. Through the primary developing operation, the first via hole upper portion 142 and a second circuit pattern hole 141 may be formed.

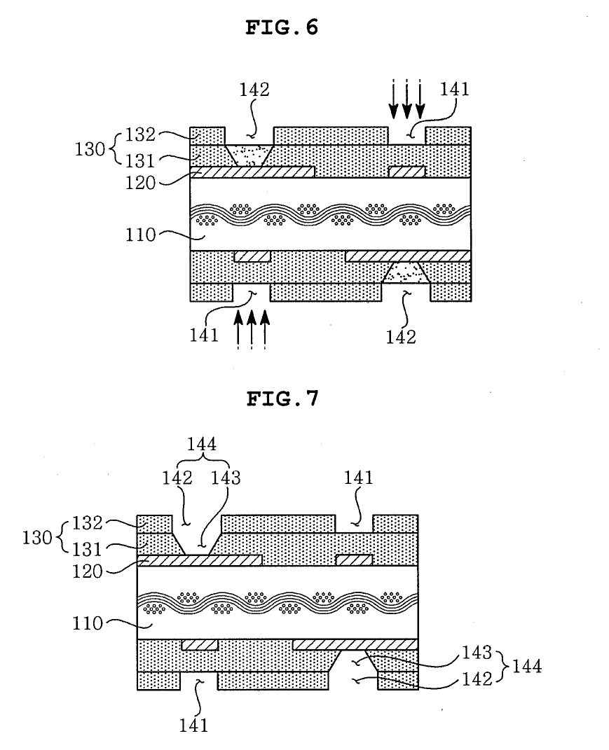

Referring to FIG. 6, a secondary exposing operation may be performed on the photosensitive insulating layer 130. The secondary exposing operation may be performed on a lower portion of the second circuit pattern hole 141. The secondary exposing operation may be performed on the non-hardened first photosensitive insulating film 131 positioned under the second circuit pattern hole 141.

Referring to FIG. 7, a secondary developing operation may be performed on the photosensitive insulating layer 130. As the secondary developing operation is performed, the first photosensitive insulating film 131 of a portion which is to become a lower portion of the first via 170 may be removed. Through such a secondary developing operation, a first via hole lower portion 143 may be formed.

By performing exposing and developing operations on the photosensitive insulating layer 130 two times according to an embodiment of the present invention, a first via hole 144 and a second circuit pattern hole 141 may be formed. In this manner, since the via hole is formed by using exposing and developing operations, a plurality of via holes may be formed without increasing a process time and cost.

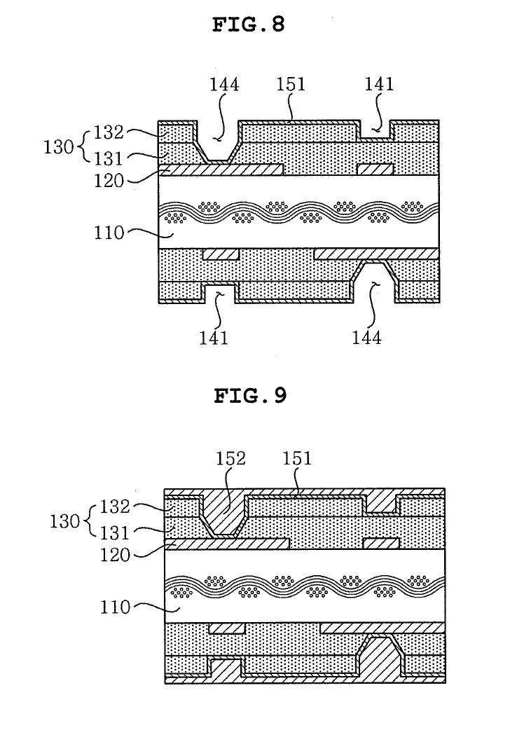

Referring to FIG. 8, a seed layer 151 may be formed on the photosensitive insulating layer 130, the first via hole 144, and the second circuit pattern hole 144. The seed layer 151 may be formed to serve as a lead-in wire for electroplating. The seed layer 151 may be formed through a wet plating method such as electroless plating method. Also, the seed layer 151 may be formed through a dry plating method such as sputtering. The seed layer 151 may be made of a conductive metal such as copper (Cu), gold (Au), nickel (Ni), or the like.

Referring to FIG. 9, a plated layer 152 may be formed on an upper portion of the seed layer 151. The plated layer 152 may be formed through an electroplating method. When electroplating is performed, the interior of the first via hole 144 and the second circuit pattern hole 141 may be filled with the plated layer 152. The plated layer 152 may be formed by using a conductive metal such as copper (Cu), gold (Au), nickel (Ni), or the like.

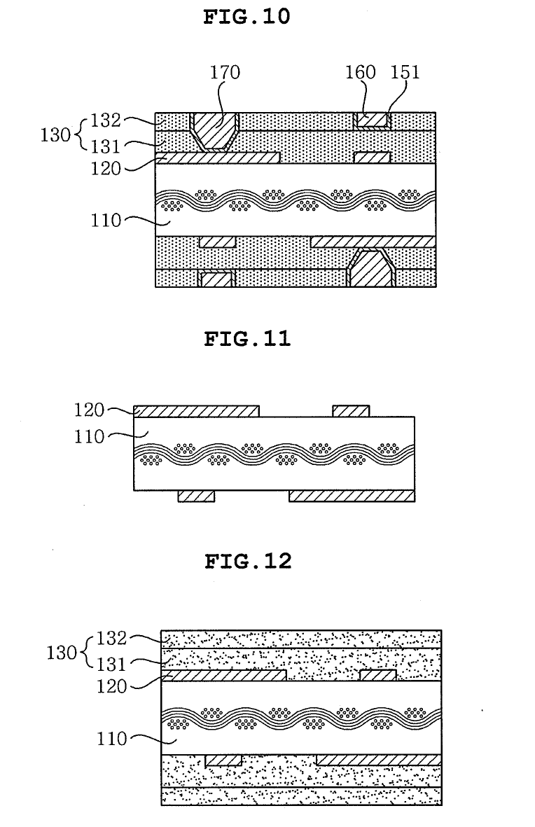

Referring to FIG. 10, the plated layer 152 and the seed layer 151 formed on the upper portion of the photosensitive insulating layer 130 may be removed. Here, the plated layer 152 and the seed layer 151 formed on the upper portion of the photosensitive insulating layer 130 may be removed by a general etching method. For example, the plated layer 152 and the seed layer 151 formed on the upper portion of the photosensitive insulating layer 130 may be removed by spraying an etching solution. Also, the plated layer 152 and the seed layer 151 formed on the upper portion of the photosensitive insulating layer 130 may be removed by polishing with a buffer, or the like. As the plated layer 152 and the seed layer 151 at the upper portion of the photosensitive insulating layer 130 are removed, the first via 170 and the second circuit pattern 160 buried within the photosensitive insulating layer 130 as illustrated in FIG. 10 may be formed.

FIGS. 11 through 19 are exemplary views illustrating a method of manufacturing a printed circuit board according to an embodiment of the present invention.

Referring to FIG. 11, the base substrate 110 with the first circuit pattern 120 formed thereon is prepared. The base substrate 110 may be made of a composite polymer resin generally used as an interlayer insulating material. For example, the PCB may be fabricated to be thinner by employing a pre-preg as the base substrate 110. Or, a fine circuit may be easily implemented by employing an Ajinomoto build up film (ABF) as the base substrate 110. Besides, the base substrate 110 may be made of an epoxy-based resin such as FR-4, BT (Bismaleimide Triazine), or the like, but the present invention is not particularly limited thereto. Also, a copper clad laminate (CCL) may be used as the base substrate 110. In an embodiment of the present invention, a CCL may be used as the base substrate 110.

The first circuit pattern 120 may be formed on an upper portion of the base substrate 110. The first circuit pattern 120 may be made of a conductive metal such as copper (Cu), gold (Au), nickel (Ni), or the like. In an embodiment of the present invention, the first circuit pattern 120 may be formed by patterning a copper foil of a copper clad laminate (CCL). Although not shown in FIG. 11, a through via may be formed to penetrate the base substrate 110.

Referring to FIG. 12, the photosensitive insulating layer 130 may be formed on an upper portion of the substrate 110 and the first circuit pattern 120. The photosensitive insulating layer 130 may include the first photosensitive insulating film 131 and the second photosensitive insulating film 132.

The first photosensitive insulating film 131 may be attached to the first circuit pattern 120 and the base substrate 110. The second photosensitive insulating film 132 may be attached to an upper portion of the first photosensitive insulating film 131. Although not shown in FIG. 12, a metal layer (not shown) may be formed on an upper portion of the second photosensitive insulating film 132. In this case, after the second photosensitive insulating film 132 is formed on an upper portion of the first photosensitive insulating film 131, the metal film (not shown) may be etched to form the second photosensitive insulating layer film 132.

The first photosensitive insulating film 131 and the second photosensitive insulating film 132 may have different levels of sensitivity. For example, the first photosensitive insulating film 131 may have a lower level of sensitivity than that of the second photosensitive insulating film 132. Or, the first photosensitive insulating film 131 may have a higher level of sensitivity than that of the second photosensitive insulating film 132. The levels of sensitivity of the first photosensitive insulating film 131 and the second photosensitive insulating film may be different according to a change in a photoinitiator, a filler, and the like. In an embodiment of the present invention, the first photosensitive insulating film 131 having a lower level of sensitivity than that of the second photosensitive insulating film 132 may be used. Also, the first photosensitive insulating film 131 and the second photosensitive insulating film 132 may be positive photosensitive insulating films.

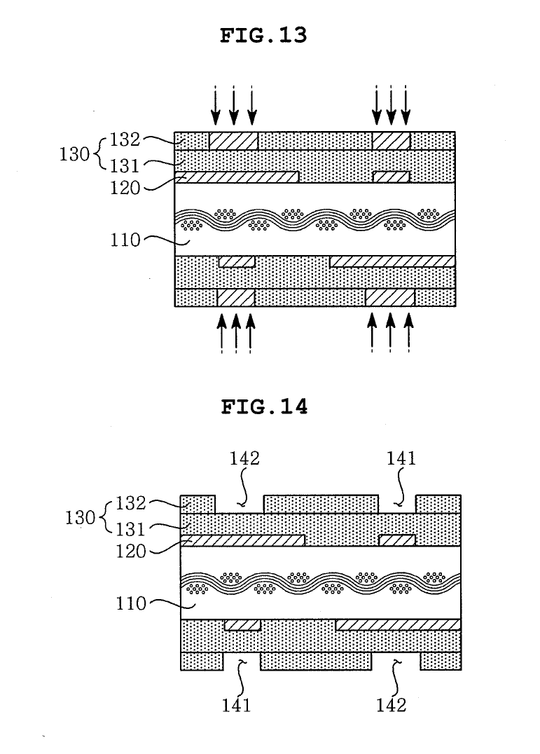

Referring to FIG. 13, a first exposing operation may be performed on the photosensitive insulating layer 130. During the first exposing operation, only the second photosensitive insulating film 132 may be exposed by adjusting the amount of exposure. Here, the exposing operation may be performed only on portions in which the second circuit pattern 160 and the first via 170 are to be formed in the second photosensitive insulating film 132.

Referring to FIG. 14, a primary developing operation may be performed on the photosensitive insulating layer 130. By performing the primary developing operation, the second photosensitive insulating film 132 at an upper portion of the first via 170 and a portion in which the second circuit pattern 160 is to be formed may be removed. Through the primary developing operation, the first via hole upper portion 142 and a second circuit pattern hole 141 may be formed.

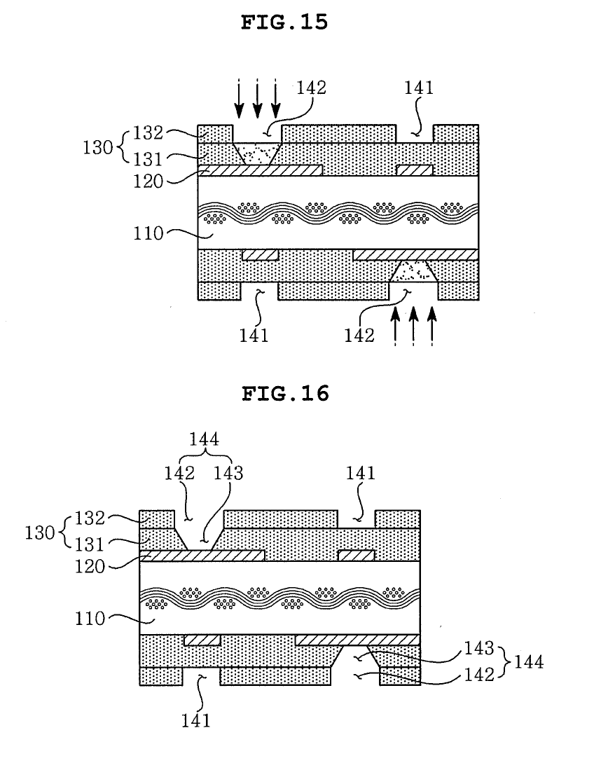

Referring to FIG. 15, a secondary exposing operation may be performed on the photosensitive insulating layer 130. The secondary exposing operation may be performed on a lower portion of the first via hole upper portion 142. Namely, the secondary exposing operation may be performed on the first photosensitive insulating film 131 positioned under the second circuit pattern hole 141.

Referring to FIG. 16, a secondary developing operation may be performed on the photosensitive insulating layer 130. As the secondary developing operation is performed, the first photosensitive insulating film 131 of a portion which is to become a lower portion of the first via 170 may be removed. Through such a secondary developing operation, a first via hole lower portion 143 may be formed.

By performing exposing and developing operations on the photosensitive insulating layer 130 two times according to an embodiment of the present invention, a first via hole 144 and a second circuit pattern hole 141 may be formed. In this manner, since the via hole is formed by using exposing and developing operations, a plurality of via holes may be formed without increasing a process time and cost.

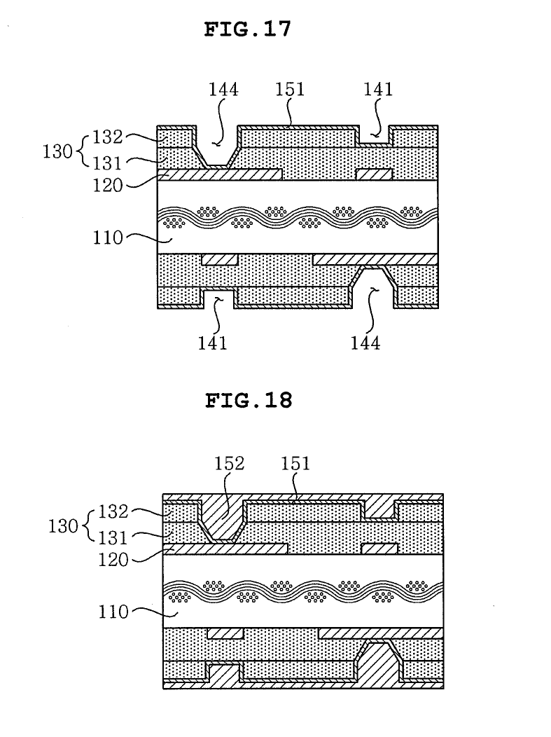

Referring to FIG. 17, a seed layer 151 may be formed on the photosensitive insulating layer 130, the first via hole 144, and the second circuit pattern hole 141. The seed layer 151 may be formed to serve as a lead-in wire for electroplating. The seed layer 151 may be formed through a wet plating method such as electroless plating method. Also, the seed layer 151 may be formed through a dry plating method such as sputtering. The seed layer 151 may be made of a conductive metal such as copper (Cu), gold (Au), nickel (Ni), or the like.

Referring to FIG. 18, a plated layer 152 may be formed on the seed layer 151. The plated layer 152 may be formed through an electroplating method. When electroplating is performed, the interior of the first via hole 144 and the second circuit pattern hole 141 may be filled with the plated layer 152. The plated layer 152 may be formed by using a conductive metal such as copper (Cu), gold (Au), nickel (Ni), or the like.

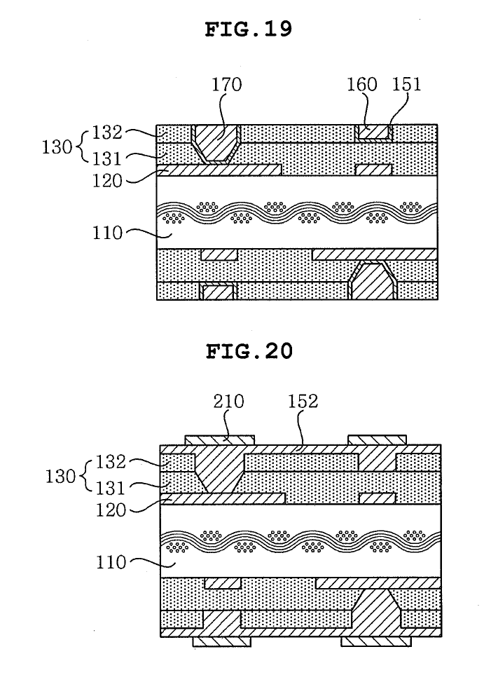

Referring to FIG. 19, the plated layer 152 and the seed layer 151 formed on the upper portion of the photosensitive insulating layer 130 may be removed. Here, the plated layer 152 and the seed layer 151 formed on the upper portion of the photosensitive insulating layer 130 may be removed by a general etching method. For example, the plated layer 152 and the seed layer 151 formed on the upper portion of the photosensitive insulating layer 130 may be removed by spraying an etching solution. Also, the plated layer 152 and the seed layer 151 formed on the upper portion of the photosensitive insulating layer 130 may be removed by polishing with a buffer, or the like. As the plated layer 152 and the seed layer 151 at the upper portion of the photosensitive insulating layer 130 are removed, the first via 170 and the second circuit pattern 160 buried within the photosensitive insulating layer 130 as illustrated in FIG. 19 may be formed.

In the case of the PCB and the method of manufacturing a PCB according to embodiments of the present invention, noise of an electrical signal can be reduced when the interlayers are electrically connected by the circuit pattern and the via formed within the photosensitive insulating layer,

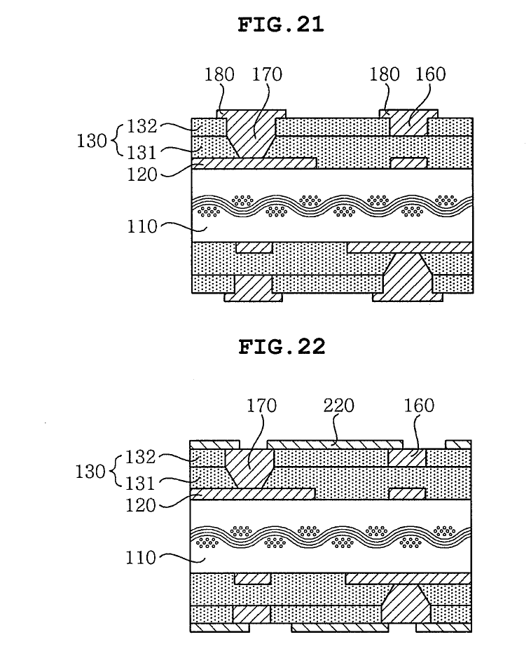

FIGS. 20 and 21 are exemplary views illustrating a method of manufacturing a printed circuit board according to another embodiment of the present invention.

Referring to FIG. 20, an etching resist 210 may be formed on an upper portion of the plated layer 152.

First, the photosensitive insulating layer 130 with the plated layer 152 formed thereon and the base substrate 110 may be provided. The first circuit pattern 120, the photosensitive insulating layer 130, and the plated layer 152 may be formed on the base substrate 110 according to the method illustrated in FIGS. 2 through 9. Alternatively, the first circuit pattern 120, the photosensitive insulating layer 130, and the plated layer 152 may be formed on the base substrate 110 according to the method illustrated in FIGS. 11 through 18.

The etching resist 210 may be formed on an upper portion of the plated layer 152. The etching resist 210 may be formed in a region in which a third circuit pattern 180 is to be formed.

Referring to FIG. 21, the third circuit pattern 180 may be formed on upper portions of the first via 170 and the second circuit pattern 160. An etching operation may be performed on the plated layer 152 with the etching resist 210 formed thereon. Then, the plated layer 152 in regions other than the region in which the etching resist 210 is formed may be removed. After the etching operation is performed, the etching resist 210 may be removed. In this manner, the third pattern 180 may be formed. Here, the third circuit pattern 180 may be a circuit pattern for electrically connecting interlayers. Also, the third circuit pattern 180 may be a connection pad for an electrical connection with the outside.

Although not shown, a seed layer may be formed under the plated layer 152 in FIGS. 20 and 21. Also, the seed layer (not shown) may be removed simultaneously when the plated layer 152 is etched, or individually removed after the plated layer 152 is etched.

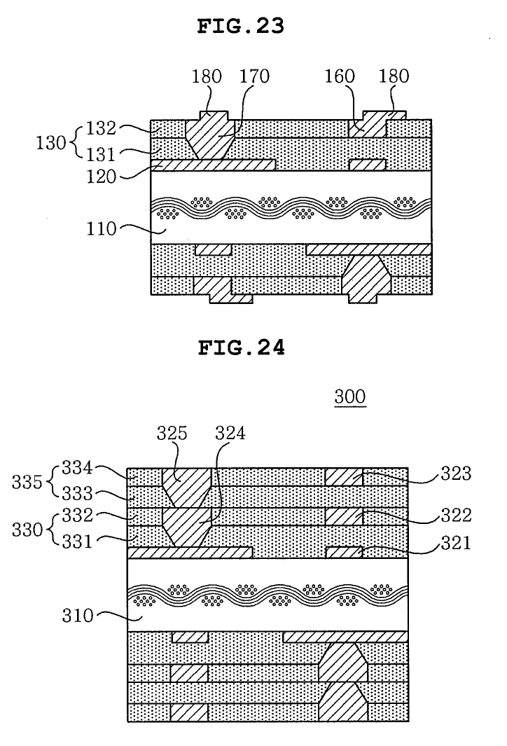

FIGS. 22 and 23 are exemplary views illustrating a method of manufacturing a printed circuit board according to another embodiment of the present invention.

Referring to FIG. 22, a plated resist 220 may be formed on at least one of upper portions of the photosensitive insulating layer 130, the first via 170, and the second circuit pattern 160.

First, the photosensitive insulating layer 130 with the first circuit pattern 120, the first via 170, and the second circuit pattern 160 formed therein and the base substrate 110 may be provided. The first circuit pattern 120, the photosensitive insulating layer 130, the first via 170, and the second circuit pattern 160 may be formed on the base substrate 110 according to the method illustrated in FIGS. 2 through 10. Alternatively, the first circuit pattern 120, the photosensitive insulating layer 130, and the plated layer 152 may be formed on the base substrate 110 according to the method illustrated in FIGS. 11 through 19.

For example, as illustrated in FIG. 22, the plated resist 220 may be formed such that an upper portion of the plated layer 152 in a region in which the third circuit pattern 180 is to be formed is exposed.

Referring to FIG. 23, the third circuit pattern 180 may be formed on upper portions of the first via 170 and the second circuit pattern 160. A plating operation may be performed on the portion exposed by the plated resist 220. After the plating operation is performed, the plated resist 220 may be removed. In this manner, the third circuit pattern 180 may be formed. Here, the third circuit pattern 180 may be a circuit pattern for electrically connecting interlayers. Also, the third circuit pattern 180 may be a connection pad for an electrical connection with the outside.

Although not shown, a seed layer may be formed under the plated layer 152 in FIGS. 22 and 23. Also, the seed layer (not shown) may be removed simultaneously when the plated layer 152 is etched, or individually removed after the plated layer 152 is etched.

The third circuit pattern 180 formed thusly is formed on an upper portion of the second circuit pattern 160 and electrically connected thereto. Namely, the dual circuit patterns may be formed. Thus, although the third circuit pattern 180 is formed to be thin, an electrical signal transmission function can be enhanced. Also, a degree of freedom of designing the third circuit pattern 180 can be enhanced by the dual structure of the second circuit pattern 160 and the third circuit pattern 180. Namely, although only a portion of the third circuit pattern 180 is electrically connected to the second circuit pattern 160 or the first via 170, an electrical signal transmission function can be maintained by the second circuit pattern 160. Namely, the shape and position of the third circuit pattern 180 may be freely selected. Also, the second circuit pattern 160 may be formed to be buried within the photosensitive insulating layer 130. Thus, the electrical signal transmission function can be enhanced and the thickness of the PCB can be reduced.

FIG. 24 is an exemplary view illustrating a printed circuit board having a multilayer structure according to an embodiment of the present invention.

FIGS. 2 through 10 and 11 through 19 illustrate a method of forming a PCB 300 by stacking a single photosensitive insulating layer using two photosensitive insulating films. Thus, by repeatedly stacking a plurality of photosensitive insulating films 331, 332, 333, and 334 and forming circuit patterns 321, 322, and 323 and vias 324 and 325, the PCB 300 having a multilayer structure including the plurality of photosensitive insulating layers 330 and 335, the circuit patterns 321, 322, and 323, and the vias 324 and 325 may be formed.

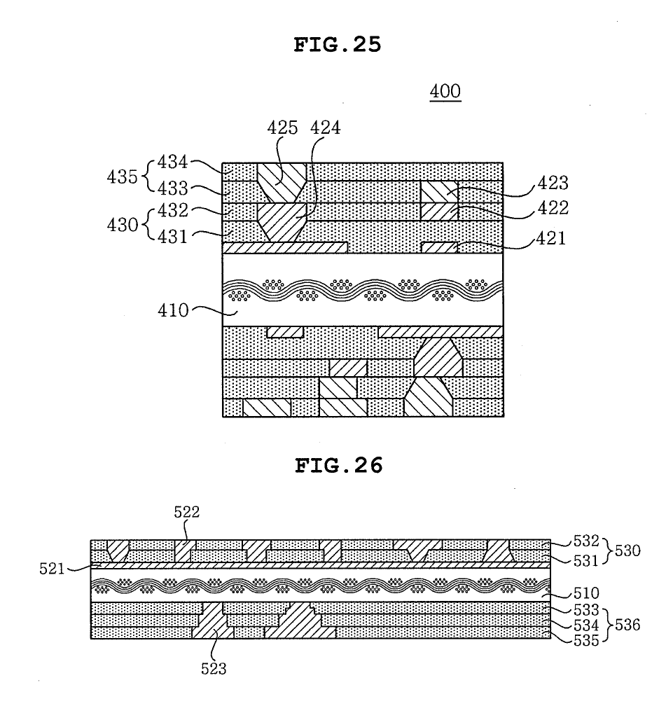

FIG. 25 is an exemplary view illustrating a printed circuit board having a multilayer structure according to another embodiment of the present invention.

Referring to FIG. 25, a PCB having a multilayer structure is illustrated.

In the PCB 400 having a multilayer structure according to an embodiment of the present invention, various circuit patterns 421, 422, and 423, and vias 424 and 425 may be formed in two photosensitive insulating layers 430 and 435. Namely, the first photosensitive insulating layer 430 and the second photosensitive insulating layer 435 may be formed to have different circuit patterns. As shown in FIG. 25, various types of circuit patterns may be configured by exposing and developing the photosensitive insulating films 431, 432, 433, and 434 constituting the photosensitive insulating layers 430 and 435, respectively.

FIG. 26 is an exemplary view illustrating a printed circuit board having a multilayer structure according to another embodiment of the present invention.

Referring to FIG. 26, an example of a PCB 500 having a multilayer structure in which an upper portion and a lower portion of a base substrate 510 have different structures is illustrated.

In the PCB 500 having a multilayer structure according to an embodiment of the present invention, a first photosensitive insulating layer 530 formed in the upper portion of the base station 510 may include two photosensitive insulating films 531 and 532. Also, in the PCB 500 according to the present embodiment, a second photosensitive insulating layer 536 formed in the lower portion of the base station 510 may include three photosensitive insulating films 533, 534, and 535. In this manner, the different numbers of photosensitive insulating films constituting the first photosensitive insulating layer 530 or the second photosensitive insulating layer 536 may be applied. By forming the photosensitive insulating layers 530 and 536 including the different numbers of photosensitive insulating films, various types of circuit patterns 521, 522, and 523 may be formed as shown in FIG. 26.

According to the PCB and the method of manufacturing a PCB according to embodiments of the present invention, since a via hole is formed by using exposure and development, a plurality of via holes can be formed without increasing a process time and cost. Also, according to the PCB and the method of manufacturing a PCB according to embodiments of the present invention, by simultaneously forming a via and a circuit pattern, a process time can be reduced. Also, according to the PCB and the method of manufacturing a PCB according to embodiments of the present invention, noise of an electrical signal can be reduced in electrically connecting interlayers by the circuit pattern and the via formed within the photosensitive insulating layer. Also, according to the PCB and the method of manufacturing a PCB according to embodiments of the present invention, since a circuit pattern and a via can be formed within and outside a photosensitive insulating layer, a degree of freedom of designing can be increased.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a base substrate;
a photosensitive insulating layer formed on an upper portion of the base substrate; and
a circuit pattern formed to be buried within the photosensitive insulating film.

2. The printed circuit board as set forth in claim 1, wherein the photosensitive insulating layer includes a first photosensitive insulating film formed on an upper portion of the base substrate and a second photosensitive insulating film formed on an upper portion of the first photosensitive insulating film.

3. The printed circuit board as set forth in claim 2, wherein the first photosensitive insulating film and the second photosensitive insulating have different levels of sensitivity.

4. The printed circuit board as set forth in claim 2, wherein the first photosensitive insulating film has a lower level of sensitivity than that of the second photosensitive insulating film.

5. The printed circuit board as set forth in claim 2, wherein the circuit pattern includes:
a first circuit pattern formed on an upper portion of the base substrate and formed to be buried within the first photosensitive insulating film;
a first via lower portion formed on an upper portion of the first circuit pattern;
a second circuit pattern formed to be buried within the second photosensitive insulating film; and
a first via upper portion formed to be buried within the second photosensitive insulating film and formed on an upper portion of the first via lower portion.

6. The printed circuit board as set forth in claim 5, further comprising:
a third circuit pattern formed on at least one of an upper portion of the second photosensitive insulating film, the first via upper portion, and an upper portion of the second circuit pattern.

7. The printed circuit board as set forth in claim 6, wherein the photosensitive insulating layer further includes a third photosensitive insulating film formed on an upper portion of the second photosensitive insulating film and formed to be buried within the third circuit pattern formed on the upper portion of the second photosensitive insulating film.

8. A method of manufacturing a printed circuit board, the method comprising:
preparing a base substrate having a first circuit pattern formed thereon;
forming a photosensitive insulating layer on an upper portion of the base substrate;
exposing and developing the photosensitive insulating layer to form a first via hole and a second circuit pattern hole; and
forming a first via and a second circuit pattern in the first via hole and the second circuit pattern hole.

9. The method as set forth in claim 8, wherein in the forming of the photosensitive insulating layer, the photosensitive insulating layer includes a first photosensitive insulating film and a second photosensitive insulating film.

10. The method as set forth in claim 9, wherein the first photosensitive insulating film and the second photosensitive insulating film have different levels of sensitivity.

11. The method as set forth in claim 9, wherein the first photosensitive insulating film has a lower level of sensitivity than that of the second photosensitive insulating film.

12. The method as set forth in claim 9, wherein the first photosensitive insulating film and the second photosensitive insulating film are formed as negative photosensitive insulating films.

13. The method as set forth in claim 12, wherein the forming of the first via hole and the second circuit pattern hole includes:
performing an exposing operation on a region other than regions in which the first via and the second circuit pattern are to be formed in the photosensitive insulating layer;
developing the second photosensitive insulating film to form the first via hole upper portion and the second circuit pattern hole;
performing an exposing operation on the first photosensitive insulating film exposed through the second circuit pattern hole; and
developing the first photosensitive insulating film to form a first via hole lower portion.

14. The method as set forth in claim 9, wherein the first photosensitive insulating film and the second photosensitive insulating film are formed as positive photosensitive insulating films.

15. The method as set forth in claim 14, wherein the forming of the first via hole and the second circuit pattern hole includes:
exposing regions of the second photosensitive insulating film in which the first via and the second circuit pattern are to be formed;
developing the exposed second photosensitive insulating film to form the first via hole upper portion and the second circuit pattern hole;
exposing the first photosensitive insulating film exposed through the first via hole upper portion; and
developing the exposed first photosensitive insulating film to form the first via hole lower portion.

16. The method as set forth in claim 9, further comprising:
after the forming of the first via and the second circuit pattern, forming a third circuit pattern on at least one of an upper portion of the second photosensitive insulating film, the via upper portion, and an upper portion of the second circuit pattern.

17. The method as set forth in claim 16, wherein the forming of the third circuit pattern includes:
forming a plated layer on an upper portion of the second photosensitive insulating film, the first via upper portion, and an upper portion of the second circuit pattern;
forming an etching resist in a region in which the third circuit pattern is to be formed;
etching the plated layer exposed by the etching resist; and
removing the etching resist.

18. The method as set forth in claim 17, wherein the plated layer is formed simultaneously when the first via and the second circuit pattern are formed.

19. The method as set forth in claim 16, wherein the forming of the third circuit pattern includes:
forming a plated resist on an upper portion of the second photosensitive insulating film and having an opening exposing the region in which the third circuit pattern is to be formed;
forming the third circuit pattern in the opening of the plated resist; and
removing the plated resist.
